(19) United States
(12) Patent Application Publication
(10) Pub. No.: US 2022/0173606 A1
(43) Pub. Date: Jun. 2, 2022

(54) Charging Control Device, Charging Control Method and Charging Control Program

(71) Applicant: Marelli Corporation, Saitama-city, Saitama (JP)

(72) Inventor: Teruyoshi Mihara, Saitama-city, Saitama (JP)

(21) Appl. No.: 17/442,033

(22) PCT Filed: Mar. 25, 2020
(86) PCT No.: PCT/JP2020/013396

§ 371 Date: Sep. 22, 2021

(30) Foreign Application Priority Data
Mar. 25, 2019 (JP) 2019-056626
Oct. 31, 2019 (JP) 2019-198446

(51) Int. Cl. H02J 7/00; G01R 31/3842; H01M 10/44; H01M 10/48; B60L 58/10; B60L 53/62

(52) U.S. Cl. CPC H02J 7/007182; H02J 7/00711; H02J 7/0048; G01R 31/3842; H02J 7/04; H01M 10/48; B60L 58/10; B60L 53/62; H01M 10/44

(57) ABSTRACT

A state estimation unit estimates an OCV upon charging a battery. Pulse charging units applies a charging pulse voltage to the battery when the OCV is larger than a first predetermined value. The state estimation unit estimates the OCV by sequentially calculating a coefficient of a transmission function based on an equivalent circuit model of the battery each time the pulse charging units apply the charging pulse voltage. The pulse charging units compare the OCV to a second predetermined value that is larger than the first predetermined value. The pulse charging units determine to apply the next pulse voltage in the pulse charging units when the estimated OCV is smaller than the second predetermined value, and determine to end charging the battery when the OCV is larger than the second predetermined value.

### CROSS-REFERENCE TO RELATED APPLICATION(S)

This application claims priority to and the benefit of Japanese Patent Application Serial No. 2019-056626, filed Mar. 25, 2019 and Japanese Patent Application Serial No. 2019-198446, filed Oct. 31, 2019, the entire disclosures of which are hereby incorporated by reference.

### TECHNICAL FIELD

The present invention relates to a charging control device, a charging control method and a charging control program.

### BACKGROUND

There is proposed a method in which on charging a secondary battery of a lithium-ion battery or the like, the secondary battery is charged by a constant current at first, and when the secondary battery is close to full charging, the charging is switched to a pulse current. After being switched to the pulse charging, an open circuit voltage (OCV) of the secondary battery is directly measured, and application timing of a charging pulse voltage is controlled on the basis of the measured value (for example, refer to Japanese Patent Laid-Open No. 2004-289976 A).

### SUMMARY

In the technology described in Japanese Patent Laid-Open No. 2004-289976 A, at the timing when the measured value of the open circuit voltage in the secondary battery becomes equal to or less than the reference voltage value, the next charging pulse voltage is applied. However, when the secondary battery becomes close to the full charging, since a difference between the open circuit voltage value OCV and the reference voltage value is made small, the time until the measured value becomes equal to or less than the reference voltage value gets longer. As a result, it takes time by the time the charging is completed.

The present invention solves the above-mentioned problem, and has an object of shortening a charging time of a battery of a secondary battery or the like.

For achieving the above-mentioned object, a charging control device according to the present invention comprises:

an estimation unit configured to estimate an open circuit voltage value of a battery, by measuring a terminal voltage value and an output current value of the battery upon charging the battery and conducting state estimation using the terminal voltage value and the measured output current value that are measured; and

a pulse charging unit configured to continue charging the battery by an application of a charging pulse voltage to the battery in a case where the open circuit voltage value that is estimated is larger than a first predetermined value, wherein

the estimation unit estimates an open circuit voltage value of the battery by sequentially calculating a coefficient of a transmission function based upon an equivalent circuit model of the battery each time the pulse charging unit applies the charging pulse voltage,

the pulse charging unit is configured to, each time the open circuit voltage value is estimated, compare the open circuit voltage value that is estimated with a second predetermined value larger than the first predetermined value,

the pulse charging unit is configured to, in a case where the open circuit voltage value that is estimated is smaller than the second predetermined value, determine an application of a next charging pulse voltage in the pulse charging unit, and

the pulse charging unit is configured to, in a case where the open circuit voltage value that is estimated is larger than the second predetermined value, determine an end of charging the battery in the pulse charging unit.

For achieving the above-mentioned object, a charging control method according to the present invention comprises:

an estimation step for executing an estimation process of an open circuit voltage value of a battery, by measuring a terminal voltage value and an output current value of the battery upon charging the battery, and conducting state estimation using the terminal voltage value and the output current value that are measured; and

a charging pulse voltage applying step for continuing charging the battery by an application of a charging pulse voltage to the battery in a case where the open circuit voltage value estimated by the estimation processing is larger than a first predetermined value, wherein the charging pulse voltage applying step comprises:

estimating an open circuit voltage value of the battery by sequentially calculating a coefficient of a transmission function based upon an equivalent circuit model of the battery each time of applying the charging pulse voltage;

comparing, each time the open circuit voltage value is estimated, the open circuit voltage value that is estimated with a second predetermined value larger than the first predetermined value;

determining, in a case where the open circuit voltage value that is estimated is smaller than the second predetermined value, an application of a next charging pulse voltage; and determining, in a case where the open circuit voltage value that is estimated is larger than the second predetermined value, an end of charging the battery.

For achieving the above-mentioned object, a charging control program according to the present invention causing a computer to execute:

an estimation step for executing an estimation process of an open circuit voltage value of a battery, by measuring a terminal voltage value and an output current value of the battery upon charging the battery and conducting estimation processing of an open circuit voltage value of the battery by state estimation using the terminal voltage value and the measured output current value that are measured; and

a charging pulse voltage applying step for continuing charging the battery by an application of a charging pulse voltage to the battery in a case where the open circuit voltage value estimated by the estimation processing is larger than a first predetermined value,

wherein the charging pulse voltage applying step comprises:

estimating an open circuit voltage value by sequentially calculating a coefficient of a transmission function based upon an equivalent circuit model of the battery each time of applying the charging pulse voltage;

comparing, each time the open circuit voltage value is estimated, the open circuit voltage value that is estimated with a second predetermined value larger than the first predetermined value;

determining, in a case where the estimated open circuit voltage value that is estimated is smaller than the second predetermined value, an application of a next charging pulse voltage; and

determining, in a case where the open circuit voltage value that is estimated is larger than the second predetermined value, an end of the charging to the battery.

According to the present invention, the estimation value of the open circuit voltage value is used as the reference, and therefore, even when the battery is close to the full charging and it takes time for the measured value of the terminal voltage value to reduce, the application of the next charging pulse voltage can quickly be determined. As a result, the time until the charging completion of the battery can be made shorter.

### BRIEF DESCRIPTION OF THE DRAWINGS

FIG. 1 is a block diagram showing the structure of a battery management system including a charging control device according to an embodiment of the present invention;

FIG. 2 is a diagram showing an internal structure of a battery;

FIG. 3A is a diagram showing a general equivalent circuit model of a lithium-ion battery;

FIG. 3B is a diagram showing a modified equivalent circuit model of a lithium-ion battery according to the embodiment in the present invention;

FIG. 4 is a graph showing a corresponding relation between an open circuit voltage value and a charging rate;

FIG. 5 is a diagram explaining timing of an application of a charging pulse voltage;

FIG. 6 is a diagram explaining transition of a terminal voltage, current and SOC in each charging mode at the battery charging;

FIG. 7 is a flow chart showing processing during the battery charging; and

FIG. 8 is a flow chart showing the details of the processing of the pulse charging in FIG. 7.

### DETAILED DESCRIPTION

Hereinafter, an explanation will be made of the details of an embodiment in the present invention with reference to the drawings as an example. However, elements described in the following embodiment are examples, and the technical scope of the present invention is not limited thereto only.

(Battery Management System)

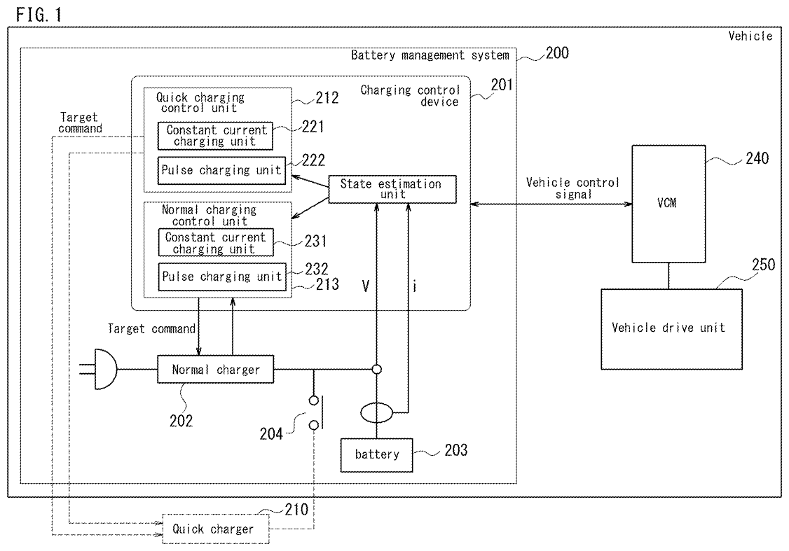

FIG. 1 is a block diagram showing the structure of a battery management system 200, including a charging control device 201 according to the embodiment.

The battery management system 200 includes the charging control device 201, a normal charger 202, a lithium-ion battery 203 (hereinafter, simply referred to as “battery 203”) and a charging change switch 204, and is configured to be capable of connecting to a quick charger 210 outside a vehicle. The quick charger 210 is a large-sized charger installed in a station, and outputs a voltage and current in response to a command of the charging control device 201 in a vehicle to quickly charge the battery 203.

In addition, the battery management system 200 receives a vehicle control signal from a vehicle control module for controlling a vehicle drive unit 250, and controls charging/discharging of the battery 203.

The charging control device 201 is provided with a state estimation unit 211, a quick charging control unit 212 and a normal charging control unit 213.

The state estimation unit 211 measures a terminal voltage value v and an output current value i of the battery 203, and estimates an open circuit voltage value OCV of the battery 203 using the measured terminal voltage value v and the measured output current value i by state estimation. The state estimation control unit 211 further estimates the charging rate SOC of the battery 203 from the estimated open circuit voltage value OCV. Hereinafter, an explanation will be made of the state estimation using a Kalman filter as an example, but the state estimation is not limited thereto.

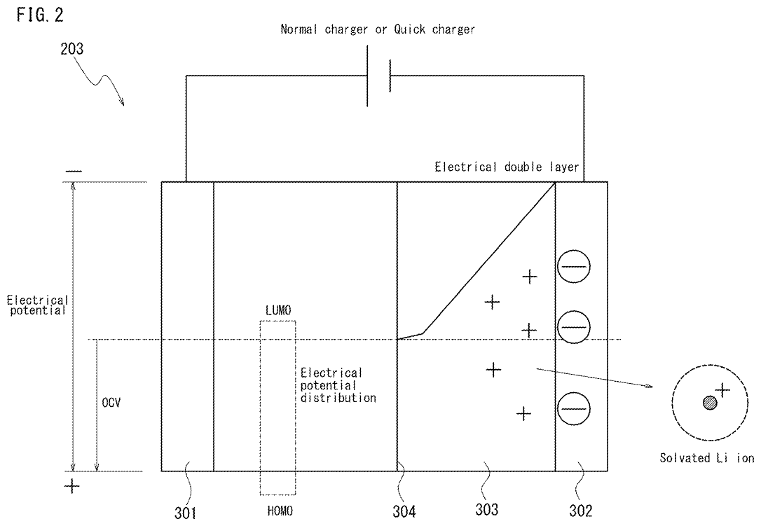

FIG. 2 is a diagram showing the internal structure of the lithium-ion battery 203. An electrolyte solution 303 in which lithium ions are solved is disposed between a positive electrode 301 and a negative electrode 302, and further, a separator 304 is disposed in the electrolyte solution 303.

The positive electrode 301 is composed of a positive-electrolyte active material for directly performing reaction exchange, a conductive aid for enhancing electron conductive property, a current collector foil (mainly, AL) for collecting electrical energies and a binder for binding the positive-electrolyte active material and the conductive aid to the current collector foil, and is a supply source of the lithium ions. The positive electrode 302 is composed of a negative-electrolyte active material, a viscosity improver (used in a case where the electrode is aqueous) for viscosity adjustment of slurry for electrode production, a current collector foil (mainly, Cu) for collecting electrical energies and a binder for binding the negative-electrolyte active material and the conductive aid to the current collector foil.

The electrolyte solution 303 plays a role of carrying Li ions for causing reaction exchange between the positive electrode 301 and the negative electrode 302, and is formed by dissolving Li salt in an organic solvent. The solvent of the electrolyte solution 303 is formed by being generally mixed with ethylene carbonate (EC), dimethyl carbonate (DMC) and the like, and the electrolyte is formed by generally using LiPF₆.

The separator 304 plays a role of preventing short-circuit between the positive electrode 301 and the negative electrode 302 and making the Li ions or the electrolyte solution 303 pass therethrough. In addition, in a case where a temperature of the battery is high at the abnormality time of overcharging or the like, the separator suppresses energization and heat generation by a shutdown function.

When a charging pulse voltage is applied from the normal charger 202 or the quick charger 210 as an external power source, the charging pulse voltage is absorbed by an electrical double layer of the negative electrode 302 and Li ions collected in the vicinity of the negative electrode 302.

The Li ions solvated on a negative active material interface uniformly align to form the electrical double layer, and the charging begins. When the electrical double layer is formed, the ions are desolvated to be dispersed into the active material. That is, the current flows via resistance components to continue the charging.

When the open circuit voltage value OCV exceeds a limit level, the battery becomes overcharged to cause various side reactions (Li precipitation and decomposition of the electrolyte solution), but in the pulse charging, the voltage is only received by the electrical double layer, and it does not mean that the open circuit voltage value OCV exceeds the limit level. That is, since the open circuit voltage value OCV does not exceed the limit, the exchange between a redox level (LUMO and HOMO) and electrons does not occur. That is, a dangerous decomposition reaction or Li precipitation of the electrolyte solution is suppressed, which is an overcharging preventive measure. It should be noted that an allowance voltage of electrical double layer is defined as a voltage in which a dangerous side reaction is suppressed in the electrode.

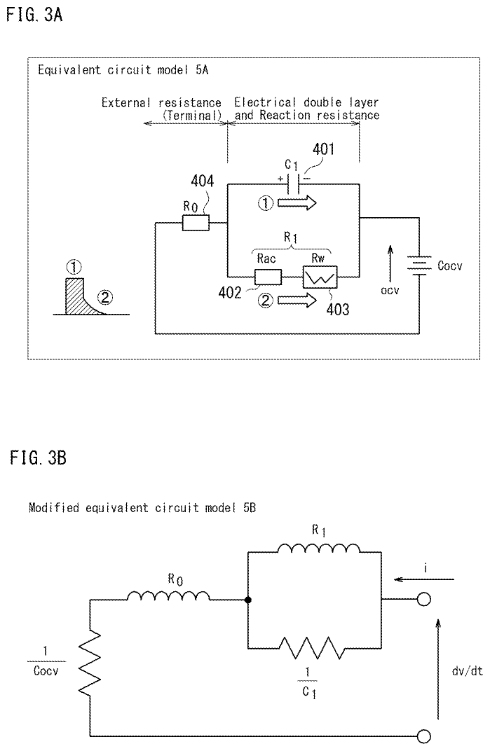

FIG. 3A is a diagram showing a general equivalent circuit model 5A of the lithium-ion battery 203. The negative active material interface may be replaced by a capacitor 401, the reaction resistance of the electrode may be replaced by a resistance 402, a dispersion resistance of the ion may be replaced by a resistance 403 and an external resistance (resistance of the terminal) may be replaced by a resistance 404. A capacitance C₁ of the capacitor 401 is equal to a capacitance of the electrical double layer. The reaction resistance of the electrode is indicated at R_{ac}, the dispersion resistance of the ion is indicated at R_{w}, and a total of two resistances is indicated at R₁. In addition, the external resistance (resistance of the terminal) is indicated at R₀. An open circuit voltage value of the capacitor C_{OCV} indicates the open circuit voltage value OCV of the battery 203.

The state estimation unit 211 finds a difference between sampling data vₖ of the inputted terminal voltage value v at a sampling time k and the previous terminal voltage value vₖ₋₁, which is indicated at a difference voltage value Δvₖ. The state estimation unit 211 estimates parameters (R₀, R₁, C₁, C_{OCV}) of four circuits in the equivalent circuit model 5A from the difference voltage value Δvₖ and an output current value i. This state estimation method is disclosed in Japanese Patent No. 5400732, and is in detail described as follows.

FIG. 3B is a diagram showing a modified equivalent circuit model 5B of the lithium-ion battery 203.

For the estimation of parameters in the embodiment of the present invention, as an example, the modified equivalent circuit model 5B as shown in FIG. 3B is used.

The modified equivalent circuit model 5B is a modification of the general equivalent circuit model 5A as shown in FIG. 3A without making an essential change thereto. Specifically the capacitor C_{OCV} and C₁ of the general equivalent circuit model 5A are respectively changed to a resistance 1/C_{OCV} and a resistance 1/C₁ of the modified equivalent circuit model 5B, and the resistances R₀ and R₁ in FIG. 3A are respectively changed to coils R₀ and R₁.

When this modified equivalent circuit model 5B is expressed by a transmission function of a continuous time, this modified equivalent circuit model 5B is expressed by the following formula that is a relation formula between a differential value of a terminal value v equivalent to the difference voltage value Δvₖ and a current value i.

$$sV ( s ) = \frac{{b}_{0}^{′} {s}^{2} + {b}_{1}^{′} s + {b}_{2}^{′}}{s + {a}_{0}^{′}} I ( s ) \qquad [ Formula 1 ]$$

where “s” is a Laplace operator in [Formula 1].

As [Formula 1] is discretized according to Tustin transform, the following formula can be obtained.

$$( z - 1 ) V ( z ) = \frac{{b}_{0} {z}^{2} + {b}_{1} z + {b}_{2}}{z - {a}_{2}} I ( z ) \qquad [ Formula 2 ]$$

where coefficients are:

$$\{ \begin{matrix}{a}_{1} = \frac{- 4}{2 {\_a}_{0}^{′} {T}_{s}} \\ {a}_{2} = \frac{2 - {a}_{0}^{′} {T}_{s}}{2 - {a}_{0}^{′} {T}_{s}} \\ {b}_{0} = \frac{4 {b}_{0}^{′} + 2 {b}_{1}^{′} {T}_{s} + {b}_{2}^{′} {T}_{s}^{2}}{2 ( 2 + {a}_{0}^{′} Ts )} \\ {b}_{1} = \frac{- 4 {b}_{0}^{′} + {b}_{2}^{′} {T}_{s}^{2}}{2 + {a}_{0}^{′} {T}_{s}} \\ {b}_{2} = \frac{4 {b}_{0}^{′} - 2 {b}_{1}^{′} {T}_{s} + {b}_{2}^{′} {T}_{s}^{2}}{2 ( 2 + {a}_{0}^{′} {T}_{s} )}\end{matrix} \qquad [ Formula 3 ]$$

and, when Tₛ is set to a sampling cycle in Tustin transform,

[Formula 1] is discretized as follows.

$$s = \frac{2}{{T}_{s}} \frac{z - 1}{z + 1} \qquad [ Formula 4 ]$$

The following formula can be obtained from the above, and four coefficients (a₂, b₀, b₁, b₂) are system-identified from an output current value i and a terminal voltage value v.

$${v}_{k} - {v}_{k - 1} = {a}_{2} ( {v}_{k - 1} - {v}_{k - 2} ) + {b}_{0} {i}_{k} + {b}_{1} {i}_{k - 1} + {b}_{2} {i}_{k - 2} \\ Δ {v}_{k} = [ {a}_{2} {b}_{0} {b}_{1} {b}_{2} ] {⌈ Δ {v}_{k - 1} {i}_{k} {i}_{k - 1} {i}_{k - 2} ]}^{T} = {θ}^{T} {φ}_{k} \qquad [ Formula 5 ]$$

where, suffix k is, as described above, the number of order in the samplings, vₖ is a terminal voltage value as k^{th} output, iₖ is an output current value as k^{th} input, Δvₖ is a differential value (difference value) of the k^{th} terminal voltage value, θ is a coefficient matrix describing a modified equivalent circuit model 5B, φ a data matrix, and a suffix T is a transposition of a matrix (vector).

Here, algorism of system identification using the most general iterative least squares technique is shown as follows.

$$\{ \begin{matrix}{K}_{k} = \frac{{P}_{k - 1} {φ}_{k}}{{φ}_{k}^{T} {P}_{k - 1} {φ}_{k} + 1} \\ {\hat{θ}}_{k} = {\hat{θ}}_{k - 1} + {K}_{k} ( {y}_{k} - {φ}_{k}^{T} {\hat{θ}}_{k - 1} ) \\ {P}_{k} = {P}_{k - 1} - {K}_{k} {φ}_{k}^{T} {P}_{k - 1}\end{matrix} \qquad [ Formula 6 ]$$

where Kₖ is a k^{th} feedback gain, Pₖ is a k^{th} covariance matrix, yₖ is a k^{th} output (differential value of a terminal voltage) and an upper suffix ^ is an estimation value. Appropriate values are given to initial values P₀ and θ₀, and the above algorism is repeated for calculation. Thereby, a coefficient to be found is identified as an estimation value θₖ.

Four circuit parameters (R₀, R₁, C₁, C_{OCV}) are found by calculation from the four coefficients found by the system identification as described above. Finally the circuit parameters can be found as follows.

$$\{ \begin{matrix}{R}_{0} = \frac{{b}_{0} - {b}_{1} + {b}_{2}}{2 ( 1 + {a}_{2} )} \\ {R}_{1} = \frac{{T}_{s} ( 1 + {a}_{2} )}{2 ( 1 - {a}_{2} )} \{ \frac{2 ( {b}_{0} - {b}_{2} ) - 2 {R}_{0} ( 1 - {a}_{2} )}{{T}_{s} ( 1 + {a}_{2} )} - \frac{{b}_{0} + {b}_{1} + {b}_{2}}{{T}_{s} ( 1 - {a}_{2} )} \} \\ {C}_{1} = {( \frac{2 ( {b}_{0} - {b}_{2} ) - 2 {R}_{0} ( 1 - {a}_{2} )}{{T}_{s} ( 1 + {a}_{2} )} - \frac{{b}_{0} + {b}_{1} + {b}_{2}}{{T}_{s} ( 1 - {a}_{2} )} )}^{- 1} \\ {C}_{OCV} = \frac{{T}_{s} ( 1 - {a}_{2} )}{{b}_{0} + {b}_{1} + {b}_{2}}\end{matrix} \qquad [ Formula 7 ]$$

Next, the state estimation unit 211 calculates an open circuit voltage value OCV using the estimated parameters and the output current value i and using the equivalent circuit model 5A as shown in FIG. 3A.

Here,

$$s O C V = \frac{1}{{C}_{O C V}} \qquad [ Formula 8 ]$$

and therefore, the following formula can be obtained by a discrete calculation to the Formula 8.

$$O C V = \frac{1}{{C}_{OCV}} \frac{{T}_{s}}{2} \frac{z + 1}{z - 1} \qquad [ Formula 9 ]$$

That is, the open circuit voltage estimation value OCVₖ can be found according to the following formula.

$$O C {V}_{k} = O C {V}_{k - 1} + \frac{{T}_{s}}{2 {C}_{O C V}} ( {i}_{k} + {i}_{k - 1} ) \qquad [ Formula 10 ]$$

The state estimation unit 211 estimates a charging rate SOC of the battery 203 from the open circuit voltage value OCV estimated by the above-mentioned method.

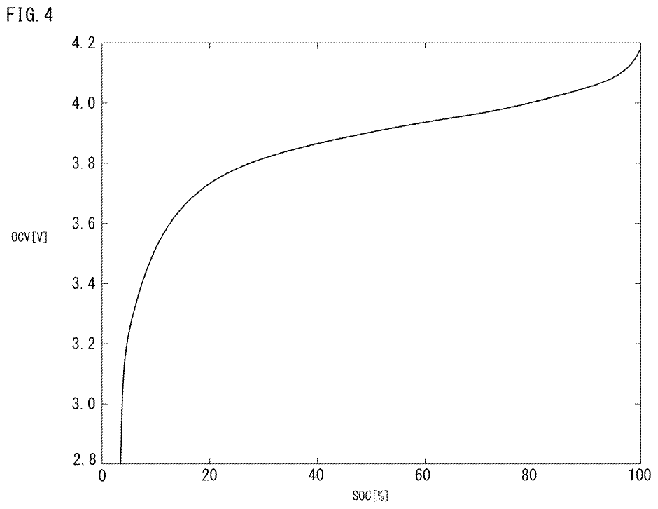

FIG. 4 is a graph showing the corresponding relation between the open circuit voltage value OCV and the charging rate SOC.

As shown in FIG. 4, the open circuit voltage value OCV and the charging rate SOC have a nonlinear corresponding relation. Therefore, data of the corresponding relation between the open circuit voltage value OCV and the charging rate SOC are in advance stored in a memory or the like of a computer forming part of the charging control device 201, and the charging rate SOC is estimated by obtaining the charging rate SOC corresponding to the estimated open circuit voltage value OCV.

The quick charging control unit 212 controls the charging by communication with a vehicle-exterior quick charger 210 installed in an external station.

The quick charging control unit 212 is provided with a constant current charging unit 221 and a pulse charging unit 222, and sends an instruction to the quick charger 210 for sequentially performing the charging by a charging mode such as preliminary charging, constant current charging (CC charging) or pulse charging based upon a state (charging rate SOC) of the battery 203 estimated in the state estimation unit 211.

In a case where the charging rate SOC estimated in the state estimation unit 211 is smaller than a predetermined value (for example, 5%), the constant current charging unit 221 performs the preliminary charging by a small constant current. In addition, in a case where the charging rate SOC estimated in the state estimation unit 211 is larger than a predetermined value (for example, 5%), the charging is performed to the battery 203 by a constant current larger than at the preliminary charging.

In a case where the charging rate SOC estimated in the state estimation unit 211 is larger than a predetermined value (for example, 80%), the pulse charging unit 222 stops the charging of the constant current to the battery 203 and applies a charging pulse voltage, of which voltage is varied in a pulse form, to the battery 203. Further, the pulse charging unit 222 causes the state estimation unit 211 to sequentially execute the estimation processing each time of applying the charging pulse voltage, and until the estimated charging rate SOC becomes larger than a predetermined value (for example, 95%), the charging pulse voltage is repeatedly applied to the battery 203.

The normal charging control unit 213 controls normal charging through communication with the in-vehicle normal charger 202 of which power is supplied from a household outlet. The normal charger 202 is installed as in-vehicle equipment on the vehicle side. The normal charger 202 takes in electricity from a system power source of a household AC distribution or the like, converts AC to DC and charges the battery 203 by a predetermined voltage and a predetermined current based upon a command of the charging control device 201.

The normal charging control unit 213 is provided with a constant current charging unit 231 and a pulse charging unit 232, and sends an instruction to the normal charger 202 for sequentially performing the charging by a charging mode such as preliminary charging, constant current charging (CC charging) or pulse charging based upon a state (charging rate SOC) of the battery 203 estimated in the state estimation unit 211.

In a case where the charging rate SOC estimated in the state estimation unit 211 is smaller than a predetermined value (for example, 5%), the constant current charging unit 231 performs the preliminary charging by a small constant current. In addition, in a case where the charging rate SOC estimated in the state estimation unit 211 is larger than a predetermined value (for example, 5%), the charging is performed to the battery 203 by a constant current larger than at the preliminary charging.

In a case where the charging rate SOC estimated in the state estimation unit 211 is larger than a predetermined value (for example, 80%), the pulse charging unit 232 stops the charging of the constant current to the battery 203 and applies a charging pulse voltage, of which voltage is varied in a pulse form, to the battery 203. Further, the pulse charging unit 232 causes the state estimation unit 211 to execute the estimation processing each time of applying the charging pulse voltage, and until the estimated charging rate SOC becomes larger than a predetermined value (for example, 95%), the charging pulse voltage is repeatedly applied to the battery 203.

The charging change switch 204 turns off at the normal charging, and turns on at the quick charging to connect the quick charger 210 to the battery 203.

It should be noted that here, a current value flowing in the battery 203 by an application of the charging pulse voltage may be equal to that at the constant current charging and the charging pulse voltage may be applied so that the current value becomes a value larger than the current value at the constant current charging.

The state estimation unit 211 estimates an open circuit voltage value OCV and further estimates the charging rate SOC from the estimated open circuit voltage value OCV. The pulse charging units 222, 232 control an application of the charging pulse voltage on the basis of the estimated charging rate SOC. The charging rate SOC and the open circuit voltage value OCV have the corresponding relation of one-to-one as shown in the graph in FIG. 4. Therefore, in the embodiment the application, the charging pulse voltage is controlled substantially on the basis of the estimated open circuit voltage value OCV.

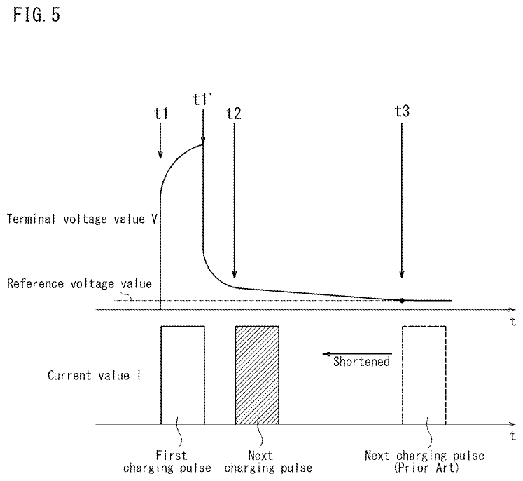

FIG. 5 is a graph explaining application timing of the charging pulse voltage in the embodiment as compared to a prior art example.

An upper side in FIG. 5 shows a terminal voltage value v and a lower side in FIG. 5 shows a current value i. When the charging pulse voltage is applied at timing t1, the terminal voltage value v greatly rises. When the application ends at timing t1′, the terminal voltage value v lowers. However, the terminal voltage value v does not return back to an original value immediately after the application of the charging pulse voltage ends, and the terminal voltage value v gradually lowers. That is, polarization generated inside the battery 203 due to the application of the charging pulse voltage disappears over time to be stable, and the terminal voltage value v gradually lowers to be closer to the open circuit voltage value OCV.

Here, in Japanese Patent Laid-Open No. 2004-289976 A as described before, the terminal voltage is directly measured, and at timing t3 when the measured value is equal to or less than a reference voltage value, the next charging pulse voltage is applied. The reference voltage value is a value approximate to the open circuit voltage value at the full charging of the battery 203, and corresponds to, in the embodiment, a second predetermined value that is described later.

However, as the battery 203 is closer to the full charging, a difference between the open circuit voltage value OCV and the reference voltage value becomes smaller. Therefore, it takes more time until the terminal voltage value v is equal to or less than the reference voltage value. That is, the time from timing t1′ to timing t3 gets long, and thereby, an application of the next charging pulse voltage is delayed and thus it takes time to complete the charging. Specifically, since the terminal voltage value v attenuates toward the open circuit voltage value OCV in an exponentially manner, it takes several hundred million seconds to several seconds to reach the reference voltage value in the vicinity of the full charging (that is, from timing t1′ to timing t3).

On the other hand, in the embodiment, the open circuit voltage is not directly measured, but is estimated as described above, using the terminal voltage value v and the output current value i. The open circuit voltage value v estimated at timing t2 immediately after the application end of the charging pulse voltage is not the terminal voltage value v at timing t2, but shows the open circuit voltage in a stable state where a sufficient time of at least timing t3 or more elapses after the battery 203 ends the discharging. In addition, a charging rate SOC is estimated from the estimated open circuit voltage value OCV, and determination is made whether or not the next the charging pulse voltage is applied based upon the charging rate SOC. Here, since the estimation of the open circuit voltage is performed at each control cycle, the estimation ends (at timing t2) at a level of several ten micro seconds after timing t1′. Therefore, as compared to the conventional technology, the determination is approximately momentarily made whether or not the next pulse voltage is applied.

In this way, in the embodiment, the determination of the application of the next charging pulse voltage can be made at timing t2 earlier than timing t3 by setting the estimated open circuit voltage value OCV as the reference. By repeating the application of the charging pulse voltage at the earlier timing, the time until the charging completion can be shortened.

There are some conventional estimation methods about the estimation of the open circuit voltage, but as described in Japanese Patent Laid-Open No. 2004-289976 A, in the conventional control in the pulse charging, not the estimation value but the actual measurement value obtained by measuring the open circuit voltage is used.

The constant voltage charging is generally performed at the time of getting close to the full charging of a battery. However, since a large voltage cannot be applied in the constant voltage charging and it takes time until the charging completion, the pulse charging is proposed. In the pulse charging, a voltage larger than the constant voltage charging is applied, though the overcharging is prevented by making the application time a short time. However, since a high voltage is applied at the pulse charging, when an error in a determination of the charging end (hereinafter, referred to as “full charging determination”) is large, overcharging may be caused.

For suppressing this overcharging, information of the open circuit voltage value OCV based upon a battery state at a time point where the application of the charging pulse voltage ends is necessary. However, the conventional estimation of the open circuit voltage does not reflect a variation of the battery state at a particular moment, that is, “immediately after the application of the charging pulse voltage”. Therefore, it is generally thought that the estimation value cannot be used in the full charging determination because of a possibility of overcharging. Therefore, for the full charging determination of the pulse charging in the prior art, an actual measurement value of the terminal voltage measured after the pulse application is used. As explained using FIG. 5, however, when the actual measurement value is used, the application of the next charging pulse voltage is delayed and it takes time to complete the charging.

Here, specified estimation methods of the open circuit voltage value OCV and the charging rate SOC are known as follows.

a) Charging rate SOC estimation by current integration: method that a value obtained by dividing electrons going in and out of a battery for a predetermined time by a charging capacity is defined as a changing amount of a charging rate

b) Method of estimating an open circuit voltage value OCV from a terminal voltage Vbat, a current Ibat and an internal resistance R (OCV=Vbat+Ibat·R)

c) Method of finding OCV by sequentially estimating equivalent circuit parameters of a battery (method used in the embodiment)

The methods of a) and b) can secure the accuracy of the estimation value in a case of monitoring charging/discharging of a battery in a relatively long time interval, but these methods do not estimate a value at a particular moment (momentary value).

Specifically the estimation value according to the method by a) does not reflect a variation of the full charging capacity, although the full charging capacity of the battery varies every minute due to external environments (temperature and the like) and aging of the battery. Therefore, in a particular moment of “immediately after applying the charging pulse voltage”, an error in a varying amount of the charging rate SOC to be calculated may become large. Therefore, the method of a) is not suitable for the full charging determination to be made each time of applying the charging pulse voltage.

In the method of b), the polarization of the battery is not considered in the definition formula (OCV=Vbat+Ibat·R). Therefore, the definition formula cannot be used for the estimation of the open circuit voltage value OCV after applying the charging pulse voltage. That is, after applying the charging pulse voltage, the current Ibat of the battery becomes 0, and therefore, the method of b) results in only monitoring the terminal voltage value v (measured value) of the battery. That is, even if the method of b) is adopted, as described in Japanese Patent Laid-Open No. 2004-289976 A, it is substantially the same as the method of determining the full charging by the actual measurement value of the terminal voltage. As similar to the conventional technology, it takes time to complete the charging.

The method of c) is adopted in the embodiment, and this method also is, conventionally as similar to a) and b), used for monitoring the charging/discharging of the battery in a relatively long time interval. However, in the method of c), a minute variation is generated each time of performing sequential calculation of the estimation value. This feature is considered not preferable in the conventional use manner, components of minute output variations are deleted for smoothing by combining other estimation methods, and then, the estimation value of the open circuit voltage is calculated.

However, while the inventor of the present application is dedicated to the research, the inventor has for the first time focused attention on that, rather, the characteristics considered as the disadvantage become an advantage since the minute variation in the estimation value for each of the sequential calculations is reflected in the monitoring of the short time interval of each application of the charging pulse voltage.

Further, the inventor of the present application has found out another advantage for using the method of c), that is, the pulse charging in the embodiment is performed on connecting a battery for vehicle drive to an external power source for charging. For example, in the charging/discharging of a battery performed during the running of a vehicle, a terminal voltage value v and an output current value i of the battery irregularly vary all the time because of various factors such as operations of an accelerator pedal and a brake, use of vehicle equipment and the like. Therefore, a width of variations in the open circuit voltage value OCV to be estimated becomes large. On the other hand, on connecting the battery to the external power source for charging, since the vehicle is not running, the estimation value of the open circuit voltage is not influenced by the factors such as the accelerator pedal, the vehicle equipment or the like. In the pulse charging also, a width of variations in a terminal voltage value v and an output current value i becomes relatively small. Under such conditions, the estimation value of the open circuit voltage as the momentary value each time of applying the charging pulse voltage is easily calculated with accuracy by using the method of c).

In this way, the inventor of the present application uses the open circuit voltage value OCV estimated by the method of c) for the full charging determination in the pulse charging based upon the novel concept. Thereby, it is made possible to shorten the charging time.

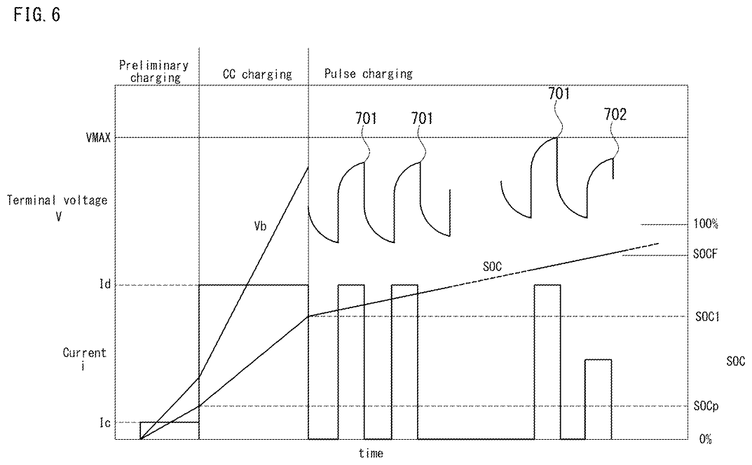

FIG. 6 is a diagram explaining transition of a terminal voltage, current and SOC in each charging mode at the battery charging. Here, an explanation will be made of the control in the quick charging control unit 212 (refer to FIG. 1), but the same control can be performed in the normal charging control unit 213 as well.

In a case where the charging rate SOC estimated in the state estimation unit 211 is equal to or less than a predetermined value SOCₚ (for example, 5%), a constant current charging unit 221 in the quick charging control unit 212 performs the preliminary charging by a small constant current (current value Ic). In addition, in a case where the charging rate SOC is larger than the predetermined value SOCₚ, the constant current charging (CC charging) is performed to the battery 203 by the current value Id larger than the current value I_{c}.

In a case where the charging rate SOC is larger than a predetermined value SOC1 (for example, 80%), a pulse charging unit 222 in the quick charging control unit 212 stops the charging of the constant current to the battery 203 and applies a charging pulse voltage 701 to the battery 203 so that a current in a pulse form of which maximum current value is Id flows in the battery, for example. Further, the pulse charging unit 222 causes the state estimation unit 211 to execute the estimation processing each time of applying the charging pulse voltage 701, and until the charging rate SOC becomes larger than a predetermined value SOCF (for example, 95%), the charging pulse voltage 701 is repeatedly applied to the battery 203. It should be noted that the predetermined values SOCₚ, SOC1, SOCF each are not limited to a specific value, but are set to meet a relation of SOCₚ<SOC1<SOCF.

When the terminal voltage value v at the time of applying the charging pulse voltage reaches a limit voltage VMAX earlier than the charging rate SOC reaching the predetermined value SOCF, a charging pulse voltage 702 of which current value is reduced to be smaller than Id is used to continue charging while preventing the terminal voltage value from surpassing the limit voltage VMAX at the time of applying the charging pulse voltage. In this way, by using the charging pulse voltage 702 of which current value is reduced, the completion of the charging can be done in a soft landing manner.

The pulse charging unit 222 repeatedly applies to the battery 203 the charging pulse voltage 701, wherein at least one of the current value and the pulse width of the charging pulse voltage 701 is made the same. The pulse charging unit 222 applies the charging pulse voltage 701 to the battery 203 in a constant interval. The pulse charging unit 222, in a case where the terminal voltage value v of the battery 203 reaches the limit voltage VMAX, applies the charging pulse voltage 702 to the battery 203. The current value of the charging pulse voltage 702 is reduced as compared to the current value used when the terminal voltage values v is smaller than the limit voltage VMAX. It should be noted that the pulse charging unit 222 may stop the charging in a case where the terminal voltage value v of the battery 203 becomes larger than the limit voltage VMAX at the time of applying the charging pulse voltage. The pulse charging unit 222 may change an off period of the charging pulse voltage 701 in response to the charging rate SOC.

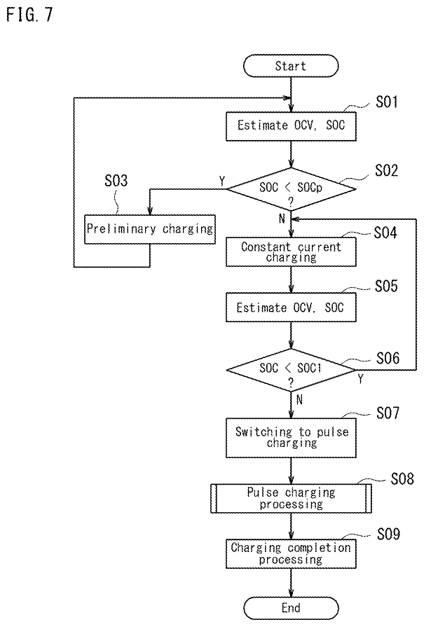

FIG. 7 is a flow chart showing the charging processing of the battery 203 in the charging control device 201.

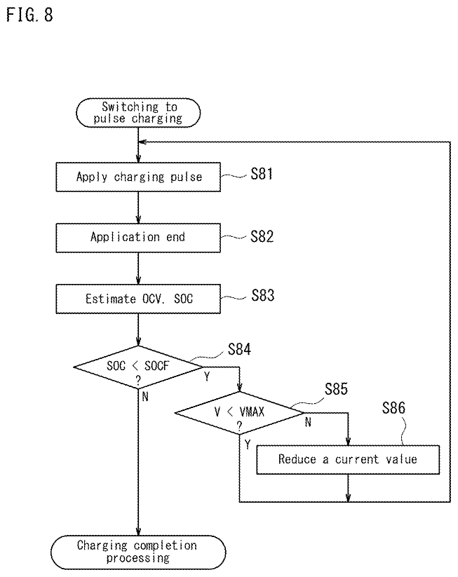

FIG. 8 is a flow chart showing the details of the pulse charging processing in FIG. 7.

Here, an explanation will be made of the processing of the quick charging control unit 212, but the normal charging control unit 213 also can execute the same processing.

When the charging of the battery 203 starts, the state estimation unit 211 estimates an open circuit voltage value OCV and further estimates a charging rate SOC from the estimated open circuit voltage value OCV (step S01). During the charging of the battery 203, the state estimation in the state estimation unit 211 is sequentially performed. The normal charging control unit 213 switches the control of the charging of the battery 203 to the preliminary charging, the constant current charging and the pulse charging on the basis of the estimated open circuit voltage value OCV and the estimated charging rate SOC.

In a case where the estimated open circuit voltage value OCV is smaller than a predetermined value SOCₚ (step S02: yes), the constant current charging unit 221 performs the preliminary charging by a small constant current (current value I_{c}) (step S03).

In a case where the estimated charging rate SOC is equal to or more than the predetermined value SOCₚ (step S02: No), the constant current charging unit 221 performs the constant current charging by the constant current (the current value Id) larger than the preliminary charging (step S04). It should be noted that the present step requires only a condition that at least the estimated charging rate SOC is larger than the predetermined value SOCₚ.

Also During the constant current charging of the battery 203, the state estimation unit 211 sequentially conducts the estimation of the open circuit voltage value OVC and the estimation of the charging rate SOC (step S05). In a case where the estimated charging rate SOC is smaller than a predetermined value SOC1 (step S06: Yes), the process returns back to step S04, wherein the constant current charging unit 231 continues the constant current charging.

In a case where the estimated charging rate SOC is equal to or more than the predetermined value SOC1 (step S06: No), the quick charging control unit 212 switches the constant current charging to the pulse charging (step S07). It should be noted that as similar to step S04, the present step also requires only a condition that at least the estimated charging rate SOC is larger than the predetermined value SOC1.

The details of the pulse charging processing in step S08 will be explained using FIG. 8.

As shown in FIG. 8, the pulse charging unit 222 in the quick charging control unit 212 applies a first charging pulse voltage to the battery 203 (step S81). At this time, the charging pulse voltage is applied so that the pulse current has, for example, a current value Id.

When the application of the first charging pulse voltage ends (step S82), the state estimation unit 211 estimates the open circuit voltage value OCV, and estimates the charging rate SOC from the estimated open circuit voltage value OCV (step S83).

The pulse charging unit 222 compares the estimated charging rate SOC with the predetermined value SOCF (step S84) to determine whether to apply the next charging pulse voltage.

The pulse charging unit 222, in a case where the estimated charging rate SOC is smaller than the predetermined value SOCF (step S84: Yes), determines the application of the next charging pulse voltage, and the process goes to step S85.

The pulse charging unit 222 compares the terminal voltage value v with the limit voltage VMAX to determine whether to change a current value of the charging pulse voltage on applying the next charging pulse voltage (step S85).

In a case where the terminal voltage value v is smaller than the limit voltage VMAX (step S85: Yes), the process goes back to step S81, wherein the pulse charging unit 222 applies the next charging pulse voltage with the same current value Id as the first current value.

In a case where the terminal voltage value v at the time of applying the pulse voltage is equal to or more than the limit voltage VMAX (step S85: No), the pulse charging unit 222 sets a charging pulse voltage of which current value Id is reduced (step S86), and the process goes back to step S81, wherein the pulse charging unit 222 applies the next charging pulse voltage. In a case of reducing the current value Id, the current value may be half of the first current value Id, for example. It should be noted that the present step S85 also requires only a condition that at least the terminal voltage value v is larger than the limit voltage VMAX.

As described above, in the pulse charging the estimation of the open circuit voltage value OVC and the estimation of the charging rate SOC are performed each time of applying the charging pulse voltage. In a case where the charging rate SOC is smaller than the predetermined value SOCF, the charging continues by repeating the processing of applying the next charging pulse voltage. In addition, In a case where the charging rate SOC is equal to or more than the predetermined value SOCF (step S84: No), as shown in step S09 in FIG. 7, the pulse charging unit 222 completes the charging processing. It should be noted that the present step S84 also requires only a condition that at least the estimated charging rate SOC is larger than the predetermined value SOCF.

As described above, according to the present embodiment, since it is possible to shorten the off period of the charging pulse voltage 701, the charging can early be terminated.

As described above, the charging control device 201 according to the embodiment comprises:

(1) the state estimation unit 221 (estimation unit) configured to estimate an open circuit voltage value OCV of the battery 203, by measuring a terminal voltage value v and an output current value i of the battery 203 upon charging the battery 203, and conducting state estimation using the measured terminal voltage value v and the measured output current value i; and the pulse charging units 222, 232 configured to continue the charging to the battery 203 by an application of the charging pulse voltage to the battery 203 in a case where the estimated open circuit voltage value OCV is larger than a first predetermined value.

The state estimation unit 211 estimates the open circuit voltage value OCV of the battery 203 by sequentially calculating a coefficient of a transmission function based upon the equivalent circuit model 5A (or the modified equivalent circuit model 5B) of the battery 203 each time the pulse charging units 222, 232 apply the charging pulse voltage.

The pulse charging units 222, 232 are configured to, each time the open circuit voltage value OCV is estimated, compare the estimated open circuit voltage value OCV with a second predetermined value larger than the first predetermined value.

The pulse charging units 222, 232 are configured to, in a case where the estimated open circuit voltage value OCV is smaller than the second predetermined value, determine an application of the next charging pulse voltage in the pulse charging units 222, 232, and

The pulse charging units 222, 232 are configured to, in a case where the estimated open circuit voltage value OCV is larger than the second predetermined value, determine an end of the charging to the battery 203 in the pulse charging units 222, 232.

When the battery 203 gets close to the full charging, it takes time for the measured value of the terminal voltage v to reduce. Therefore, if the determination whether to apply the charging pulse voltage is made after the measured value of the terminal voltage v is close to the open circuit voltage value OCV, the timing of the application is delayed and the time until the charging is completed is made long.

In the embodiment, the terminal voltage value and the output current value are used to estimate the open circuit voltage value OCV, and the determination whether to apply the charging pulse voltage is made on the basis of the measured value. Thereby, the application of the next charging pulse voltage can quickly be determined, and as a result, the time until the charging completion of the battery 203 can be made shorter.

Further, for the calculation of the estimation value of the open circuit voltage value OCV, the embodiment uses the method of sequentially calculating the coefficient of the transmission function based upon the equivalent circuit model 5A (or the modified equivalent circuit model 5B as the change to this) of the battery 203. By this method, in the monitoring of the short time interval as each application of the charging pulse voltage, it is possible to calculate the estimation value reflecting the minute variation and it can be appropriately determined whether to perform the next application of the charging pulse voltage.

In the specific processing in the embodiment, the switching to the pulse charging and the application of the next charging pulse voltage are determined on the basis of the charging rate SOC further estimated from the estimated open circuit voltage value OCV. However, as described before, the open circuit voltage value OCV and the charging rate SOC have the corresponding relation of one-to-one (refer to FIG. 4). Accordingly, it can be said that the determination of the application is substantially made on the basis of the estimated open circuit voltage value OCV. “The first predetermined value of the open circuit voltage value OCV” corresponds to “the predetermined value SOC1 of the charging rate SOC”, and “the second predetermined value of the open circuit voltage value OCV” corresponds to “the predetermined value SOCF of the charging rate SOC”

It should be noted that the pulse charging units 222, 232 compare the estimated open circuit voltage value OCV instead of the charging rate SOC with the first predetermined value and the second predetermined value, and may determine the switching to the pulse charging and the application of the next charging pulse voltage.

(2) The pulse charging units 222, 232 apply the next charging pulse voltage before the terminal voltage value v becomes smaller than the second predetermined value after applying the charging pulse voltage.

As shown in FIG. 5, the pulse charging units 222, 232 may determine whether to apply the next charging pulse voltage as soon as the sequential estimation of the open circuit voltage value OCV is completed. Thereby, the application of the charging pulse voltage can be performed earlier than the timing t3 when the measured terminal voltage value v lowers to the reference voltage value (the second predetermined value). In this way, the quick application of the charging pulse voltage is repeated, and as a result, the time until the charging completion can be made short.

(3) The pulse charging units 222, 232 apply, in a case where the terminal voltage value v of the battery 203 on applying the charging pulse voltage v is larger than the limit voltage VMAX (third predetermined value), the next charging pulse voltage of which current value is reduced to be lower than the charging pulse voltage.

Thereby, it is possible to continue the charging in a way that the charging pulse voltage v does not exceed the limit voltage VMAX.

### Other Embodiment

As described above, the present invention of this application is explained with reference to the embodiment, but the present invention is not limited to the embodiment. The structure and the details of the present invention can be modified variously to the extent that those skilled in the art can understand within the scope of the technical concept of the present invention. In addition, systems, methods and devices in which different features included in the respective embodiments are combined in any way are also contained within the scope of the technical concept of the present invention.

In addition, the present invention may be applied to a system composed of a plurality of devices, or a single device. Further, the present invention is applicable also to a case where an information processing program for realizing the function in the embodiment is supplied to systems or devices directly or from a remote site. Accordingly, for realizing the function of the present invention with a computer, a program installed in the computer, a medium stored in the program, or a WWW (World Wide Web) server downloading the program is also contained within the scope of the present invention. Particularly, a non-transitory computer readable medium for storing therein a program causing a computer to execute processing steps included in the above-described embodiments is also contained within the scope of the present invention.

### REFERENCE SIGNS LIST

5A: general equivalent circuit model

5B: modified general equivalent circuit model

200: battery management system

201: charging control device

202: normal charger

203: battery

210: quick charger

211: state estimation unit

212: quick charging control unit

213: normal charging control unit

221,231: constant current charging unit

222,232: pulse charging unit

240: VCM

250: vehicle drive unit

301: positive electrode

302: negative electrode

303: electrolyte solution

304: separator

401: capacitor

402-404: resistance

701,702: charging pulse voltage

1. A charging control device comprising:
an estimation unit configured to estimate an open circuit voltage value of a battery, by measuring a terminal voltage value and an output current value of the battery upon charging the battery and conducting state estimation using the terminal voltage value and the output current value; and
a pulse charging unit configured to continue charging the battery by an application of a charging pulse voltage to the battery in a case where the open circuit voltage value is larger than a first predetermined value, wherein
the estimation unit estimates the open circuit voltage value of the battery by sequentially calculating a coefficient of a transmission function based upon an equivalent circuit model of the battery immediately after ending the application of the charging pulse voltage,
the pulse charging unit is configured to, when the open circuit voltage value is estimated, compare the open circuit voltage value with a second predetermined value larger than the first predetermined value,
the pulse charging unit is configured to apply a next charging pulse voltage in a case where the open circuit voltage value is smaller than the second predetermined value so that the application of charging pulse voltage is conducted in cycles, and
the pulse charging unit is configured to end charging the battery in a case where the open circuit voltage value is larger than the second predetermined value.

2. (canceled)

3. The charging control device according to claim 1, wherein
the pulse charging unit applies, in a case where the terminal voltage value of the battery on applying the charging pulse voltage is larger than a third predetermined value, a next charging pulse voltage of which current value is reduced to be lower than the charging pulse voltage.

4. A charging control method comprising:
an estimation step for executing an estimation process of an open circuit voltage value of a battery, by measuring a terminal voltage value and an output current value of the battery upon charging the battery, and conducting state estimation using the terminal voltage value and the output current value; and
a charging pulse voltage applying step for continuing charging the battery by an application of a charging pulse voltage to the battery in a case where the open circuit voltage value is larger than a first predetermined value,
wherein the charging pulse voltage applying step comprises:
estimating the open circuit voltage value by sequentially calculating a coefficient of a transmission function based upon an equivalent circuit model of the battery immediately after ending the application of the charging pulse voltage;
comparing, when the open circuit voltage value is estimated, the open circuit voltage value with a second predetermined value larger than the first predetermined value;
applying a next charging pulse voltage in a case where the open circuit voltage value is smaller than the second predetermined value so that the application of charging pulse voltage is conducted in cycles; and
ending charging the battery in a case where the estimated open circuit voltage value is larger than the second predetermined value.

5. A non-transitory computer readable storage medium storing a charging control program causing a computer to execute:
an estimation step for executing an estimation process of an open circuit voltage value of a battery, by measuring a terminal voltage value of and an output current value of the battery upon charging the battery and conducting state estimation using the terminal voltage value and the output current value; and
a charging pulse voltage applying step for continuing charging the battery by an application of a charging pulse voltage to the battery in a case where the open circuit voltage value is larger than a first predetermined value,
wherein the charging pulse voltage applying step comprises:
estimating the open circuit voltage value by sequentially calculating a coefficient of a transmission function based upon an equivalent circuit model of the battery immediately after ending the application of the charging pulse voltage;
comparing, when the open circuit voltage value is estimated, the open circuit voltage value with a second predetermined value larger than the first predetermined value;
applying a next charging pulse voltage, in a case where the open circuit voltage value is smaller than the second predetermined value so that the application of charging pulse voltage is conducted in cycles; and
ending charging the battery in a case where the open circuit voltage value is larger than the second predetermined value.
